(19) United States
(12) Patent Application Publication
(10) Pub. No.: US 2015/0187540 A1
(43) Pub. Date: Jul. 2, 2015

(54) DRAWING APPARATUS AND METHOD OF MANUFACTURING ARTICLE

(71) Applicant: CANON KABUSHIKI KAISHA, Tokyo (JP)

(72) Inventors: Atsushi Ito, LONG BEACH, CA (US); Nobushige Korenaga, Utsunomiya-shi (JP)

(21) Appl. No.: 14/580,060

(22) Filed: Dec. 22, 2014

(30) Foreign Application Priority Data
Dec. 27, 2013 (JP) 2013-272044

(51) Int. Cl. H01J 37/20; H01J 37/30; H01J 37/317

(52) U.S. Cl. CPC H01J 37/20; H01J 37/3174; H01J 37/3007; H01J 2237/15; H01J 2237/2007; H01J 2237/20292; H01J 2237/3173

(57) ABSTRACT

A drawing apparatus includes a plurality of optical systems, each of which irradiates with a beam a substrate, corresponding thereto, having a predetermined size, and a plurality of holders, each of which is movable and holds the substrate corresponding thereto. The drawing apparatus is configured to perform drawing on a plurality of the substrate respectively held by the plurality of holders with respective beams respectively by the plurality of optical systems with the plurality of holders being scanned relative to the plurality of optical systems in a scan direction, and in a direction orthogonal to the scan direction, an interval between two adjacent optical systems of the plurality of optical systems is smaller than a sum of a length of one of the plurality of holders and the size.

### BACKGROUND

1. Field of the Invention

The present invention relates to a drawing apparatus that performs drawing on a substrate with a beam, and a method of manufacturing an article.

2. Description of the Related Art

An example of a drawing apparatus that performs drawing on a substrate with a beam is an electron beam drawing apparatus having an electron gun that generates an electron beam, an electron optical system for irradiating a substrate with an electron beam, and a movable holder that holds the substrate. In consideration of drawing processing throughput (productivity), there have been proposed an electron beam drawing apparatus that performs drawing on a substrate with a large number of electron beams. Further, there have also been proposed a so-called “cluster system” that integrates multiple electron beam drawing apparatuses into one system to enhance the productivity (PCT Japanese Translation Patent Publication No. 2012-518902).

A structural body (cluster system) including multiple charged-particle lithography apparatuses that is described in PCT Japanese Translation Patent Publication No. 2012-518902 has an advantage in terms of productivity enhancement, but results in a considerable increase in installation area, thus leading to little improvement in productivity per unit area.

### SUMMARY OF THE INVENTION

The present disclosure provides, for example, a drawing apparatus having an advantage in terms of productivity per unit area.

According to an aspect disclosed herein, a drawing apparatus includes a plurality of optical systems each of which irradiates with a beam a substrate, corresponding thereto, having a predetermined size, and a plurality of holders each of which is movable and holds the substrate corresponding thereto. The drawing apparatus is configured to perform drawing on a plurality of the substrates respectively held by the plurality of holders with respective beams respectively by the plurality of optical systems with the plurality of holders being scanned relative to the plurality of optical systems in a scan direction, and in a direction orthogonal to the scan direction, an interval between two adjacent optical systems of the plurality of optical systems is smaller than a sum of a length of one of the plurality of holders and the size.

According to another aspect disclosed herein, a drawing apparatus includes a plurality of optical systems, each of which irradiates with a beam a substrate, corresponding thereto, having a predetermined size, and a plurality of holders, each of which is movable and holds the substrate corresponding thereto. The drawing apparatus is configured to perform drawing on a plurality of the substrates respectively held by the plurality of holders with respective beams respectively by the plurality of optical systems with the plurality of holders being scanned relative to the plurality of optical systems in a scan direction, and the drawing apparatus includes a stage configured to support the plurality of holders, and to allow the plurality of holders to be moved independently, and having a movable range not smaller than the size in the scan direction.

Further features of the present invention will become apparent from the following description of exemplary embodiments with reference to the attached drawings.

### BRIEF DESCRIPTION OF THE DRAWINGS

FIG. 1 is a diagram illustrating a configuration example of a drawing apparatus.

FIG. 2 is a diagram illustrating the details of the configuration example of the drawing apparatus.

FIG. 3 is a diagram illustrating a configuration example of an electron optical system.

FIGS. 4A, 4B, and 4C are diagrams illustrating drawing processing.

### DESCRIPTION OF THE EMBODIMENTS

### First Embodiment

Hereinafter, embodiments of the invention will be described with reference to the attached drawings. Note that throughout the attached drawings for explaining the embodiments, the same components are basically (unless otherwise stated) denoted by the same reference numerals, and repeated explanation of the components is omitted.

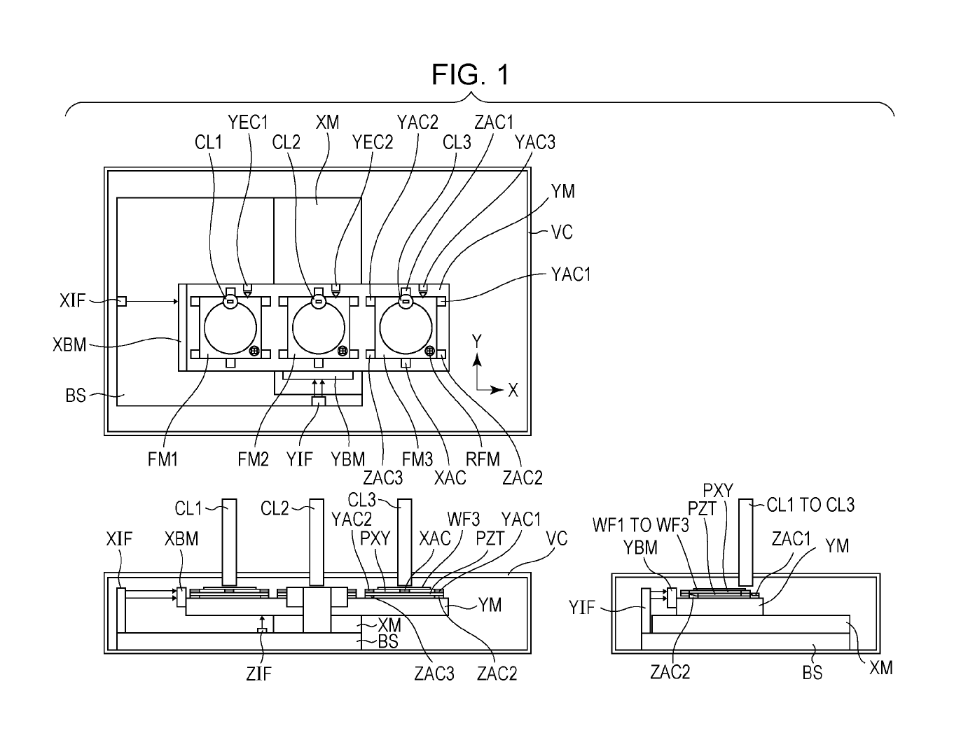

FIG. 1 is a diagram (including three views from three angles) illustrating a configuration example of a drawing apparatus. The drawing apparatus may be an apparatus (maskless lithography apparatus) that performs drawing (patterning) on a wafer (substrate) of a predetermined size (300 mm in diameter, for example) without using a mask (an original), the drawing apparatus using a radiation beam (also simply referred to as a beam) such as a charged-particle beam. A description is herein given of an example in which electron beams are used as the charged-particle beams. In FIG. 1, three electron-optical-system columns (barrels) CL1, CL2, and CL3 are arranged side by side (in an X-axis direction) away from each other in an upper portion of a vacuum chamber VC. The electron-optical-system columns CL1 to CL3 are herein each illustrated as being composed of a single electron-optical-system column, but may be composed of multiple electron-optical-system columns, thus being referred to as an electron-optical-system-column group composed of one or more electron-optical-system columns. Accordingly, the drawing apparatus according to the present embodiment includes three electron-optical-system-column groups. Note that the electron-optical-system-column group is also simply referred to as an electron optical system (group) or a column (group).

A stage base BS is fixed on the bottom of the vacuum chamber VC and supports long-stroke stages (also simply referred to as stages) including an X moving member XM and a Y moving member YM. Specifically, the X moving member XM is attached to the stage base BS in such a manner as to be movable in the X-axis direction, and the Y moving member YM is attached to the X moving member XM in such a manner as to be movable in a Y-axis direction. The direction in which a wafer is scanned is herein referred to as the Y-axis direction, and the direction orthogonal to the scanning direction (scan direction) is referred to as the X-axis direction. The Y moving member YM supports short-stroke stages (also referred to as holders) FM1, FM2, and FM3 each of which holds a wafer and is movable. The short-stroke stages FM1 to FM3 are designed to be of the same size and are arranged in such a manner as to face the electron-optical-system columns CL1 to CL3, respectively. The short-stroke stages FM1 to FM3 each include an upper movable plate PXY that is movable in the X-axis direction, in the Y-axis direction, and around a Z-axis. Actuators (driving devices) XAC, YAC1, and YAC2 for moving the upper movable plate PXY in the X-axis direction, in the Y-axis direction, and around the Z-axis, respectively, are supported by a lower movable plate PZT that is movable in a Z-axis direction, around the X-axis, and around the Y-axis. Actuators ZAC1, ZAC2, and ZAC3 for moving the lower movable plate PZT in the Z-axis direction, around the X-axis, and around the Y-axis, respectively, are supported by the Y moving member YM. The configuration described above enables fine motions of the short-stroke stages FM1 to FM3 (three of the upper movable plate PXY) independently in the X-axis direction, in the Y-axis direction, in the Z-axis direction, around the X-axis, around the Y-axis, and around the Z-axis, that is, in six degrees of freedom. The actuators XAC, YAC1, YAC2, ZAC1, ZAC2, and ZAC3 may each include a deceleration mechanism, a friction element, or both a deceleration mechanism and a friction element. With this configuration, even if the actuators XAC, YAC1, YAC2, ZAC1, ZAC2, and ZAC3 are separated from a control system, positions related to the six degrees of freedom of the short-stroke stages (three of the upper movable plate PXY) are kept.

Each upper movable plate PXY is provided with: a chuck (not illustrated) for holding a wafer WF; and a reference member RFM. The reference member RFM includes a reference mark (reference pattern) and a reference surface. A detection unit (detector) 12, to be described later, that is provided for each column group can detect the position of the reference mark in an X-Y plane, by using light. The detection unit 12 can also detect the height (position in the Z-axis direction) of the reference surface. The reference member RFM includes another reference mark (reference pattern) near the reference mark described above, the other reference mark enabling the detection unit 12 to detect the position, of the other reference mark, related to the three degrees of freedom (in the X-axis, Y-axis, and Z-axis directions), irradiated by the corresponding electron-optical-system column with an electron beam.

The Y moving member YM is movable relative to the X moving member XM not only in the Y-axis direction, but also in the X-axis direction, around the Z-axis, around the X-axis, and around the Y-axis. The Y moving member YM is also provided with a Y-axis-direction-position measurement mirror YBM and an X-axis-direction-position measurement mirror XBM. With this configuration, measurement units (measurement devices or interferometers) can measure positions, of the Y moving member YM, in the X-axis, Y-axis, and Z-axis directions, around the Z-axis, around the X-axis, and around the Y-axis. Specifically, an X interferometer XIF provided on the stage base BS measures the position, in the X-axis direction, of the Y moving member YM and the position (angle), around the Y-axis, of the Y moving member YM, by using the X-axis-direction-position measurement mirror XBM. A Y interferometer YIF provided on the stage base BS measures the position, in the Y-axis direction, of the Y moving member YM and the positions (angles), around the Z-axis and around the X-axis, of the Y moving member YM, by using the Y-axis-direction-position measurement mirror YBM. Further, a Z interferometer ZIF provided on the stage base BS measures the position, in the Z-axis direction, of the Y moving member YM.

Here, operation of the drawing apparatus according to the present embodiment will be described. Firstly, with the vacuum chamber VC being in a vacuum state, the short-stroke stages FM1, FM2, and FM3 respectively hold wafers WF1, WF2, and WF3 transported by a transport system (not illustrated). Next, the X moving member XM and the Y moving member YM are moved to place each alignment mark on the corresponding wafer at a position where the detection unit 12 provided for the wafer can detect the alignment mark. Each detection unit 12 measures positions, of the alignment mark, related to the three degrees of freedom (in the X-axis, Y-axis, and Z-axis directions) by using light. The measurement is repeated for multiple predetermined alignment marks, and thereby pieces of information L1, L2, and L3 regarding drawing-target-region coordinates related to the six degrees of freedom are acquired for the wafers WF1, WF2, and WF3, respectively.

Then, the X moving member XM and the Y moving member YM are moved so that the reference mark of each reference member RFM can move under a corresponding one of the electron-optical-system columns (column group) CL1 to CL3. The detection units 12 detect scattered electrons obtained by emitting the electron beams from the electron-optical-system columns CL1 to CL3 to the reference members RFM, and thereby pieces of information E1, E2, and E3 regarding reference-surface (image-surface) coordinates related to the six degrees of freedom are acquired.

Based on the pieces of information L1, L2, and L3 regarding drawing-target-region coordinates related to the six degrees of freedom of the wafers and the pieces of information E1, E2, and E3 regarding reference-surface coordinates related to the six degrees of freedom, reference surfaces of the electron-optical-system columns CL1 to CL3 are aligned with the drawing target regions of the respective wafers. In other words, the short-stroke stages FM1 to FM3 (three of the upper movable plate PXY) are moved to achieve the alignment. Note that each of the actuators XAC, YAC1, and YAC2 is designed to have a driving stroke (movable range in which each short-stroke stage is movable in the X-axis and Y-axis directions) greater than an amount of electron beam deflection (movable range of the electron beams on a substrate) performed by a deflector (to be described later) of the corresponding electron-optical-system column. Each of the actuators XAC, YAC1, and YAC2 is also designed to have a driving resolution lower than the amount of electron beam deflection. Each of the actuators ZAC1, ZAC2, and ZAC3 is designed to have a driving stroke higher than a focal depth of the electron beams and a driving resolution lower than the focal depth. An example of an actuator eligible for the actuator having the foregoing driving stroke, the driving resolution, and the position keeping function in spite of not being controlled (no electrical supply) is an actuator that drives a piezoelectric element intermittently, but is not limited thereto.

The configuration as described above leads to an advantage in terms of adjustment of a positional error occurring in the drawing target region to a value that is equal to or lower than the amount of electron beam deflection of the electron-optical-system column and the focal depth of the electron beams, the positional error occurring due to, for example, an error of substrate placement on the short-stroke stage. If the measurement for acquiring the pieces of information L1, L2, and L3 regarding drawing-target-region coordinates related to the six degrees of freedom is performed again after the adjustment as described above, a residual after the adjustment can be obtained. The residual can be reduced by driving the deflector of each electron-optical-system column, the short-stroke stage, or the like. In this manner, the adjustment can be performed so that the three sets of electron-optical-system columns and the respective drawing target regions of the wafers can be considered to have an equal relative positional relationship. For this reason, by moving the X moving member XM and the Y moving member YM after the adjustment, the drawing operations can be performed on the wafers in parallel.

Here, an important point is that adjacent ones of the electron-optical-system columns CL1 to CL3 are arranged substantially the same distance or interval (can be regarded as the same distance or interval) away from each other in the X-axis direction and that adjacent ones of the short-stroke stages FM1 to FM3 are arranged substantially the same distance (can be regarded as the same distance) away from each other in the X-axis direction. Another point is that each actuator that moves the short-stroke stage in the X-Y plane has a higher driving stroke than an amount of electron beam deflection and a lower driving resolution than the amount of electron beam deflection. With the configuration as described above, an error of wafer placement with respect to the electron-optical-system column can be adjusted to be equal to or lower than the amount of electron beam deflection by moving the short-stroke stage, and the residual in the adjustment can be compensated by using the deflector. Accordingly, even if drawing operations are performed in parallel on the wafers WF1 to WF3 while moving the X and Y moving members XM and YM shared by the wafers WF1 to WF3, the drawing operations do not have a disadvantage in terms of the precision with which a pattern to be drawn is positioned and overlapped.

In addition, the distance between adjacent ones of the electron-optical-system columns in the X-axis direction is desirably shorter than the sum of the length (size) of one of the short-stroke stages and the size of the corresponding wafer. Note that the distance needs to be longer than the length of each short-stroke stage to avoid interference between the short-stroke stages. In a configuration in which a long-stroke moving stage is moved relative to each of electron-optical-system columns independently, the sum of the size of the short-stroke stage and the size of the wafer in the X-axis direction is used as a required distance in the X-axis direction between adjacent electron-optical-system columns. The configuration according to the present embodiment uses a distance in the X-axis direction between adjacent ones of the electron-optical-system columns that is shorter than the sum described above. Thus, the present embodiment leads to a smaller foot print than in the conventional configuration in which three electron-optical-system columns and three stages are simply arranged separately from each other, and thus has an advantage in terms of productivity (throughput) per unit area. The case where multiple electron-optical-system columns are arranged in such a manner as (to be considered) to be equally spaced away from each other in the X-axis direction has heretofore been described, but the present embodiment is not limited thereto. For example, if being projected on the X-axis, multiple electron-optical-system columns may be arranged in such a manner as to (be considered to) be equally spaced away from each other on the X-axis. In this case, the multiple electron-optical-system columns may be arranged in not only a line but also multiple lines.

Meanwhile, it is desirable to provide sensors (measuring units) that measure the positions of short-stroke stages with respect to a Y moving member. Only sensors YEC1, YEC2, and YEC3 among the sensors are illustrated in the top view in FIG. 1, the sensors YEC1, YEC2, and YEC3 measuring the positions of the short-stroke stages FM1 to FM3 in the Y-axis direction. Desirable examples of the sensors include an encoder or an interferometer having a function of measuring an absolute position with high resolution and accuracy, but are not limited thereto. Similar sensors may be provided for other degrees of freedoms. The sensors may be used for controlling movement of the short-stroke stages. In addition, in a case where a relative positional relationship between a Y-moving-member measurement mirror and a corresponding short-stroke stage is changed due to a change with time such as a thermal deformation accompanying the drawing operations, each sensor can be used for measuring and compensating the relative position.

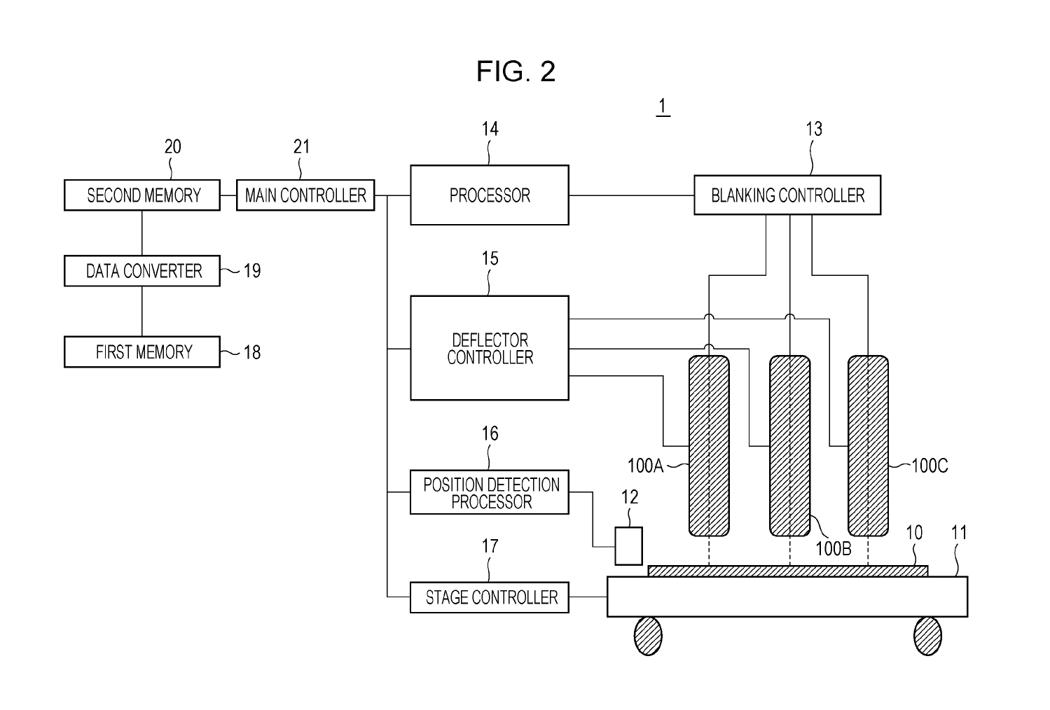

FIG. 2 is a diagram illustrating a configuration example applicable to the drawing apparatus according to the present embodiment and particularly illustrates the details of controllers. In FIG. 2, a drawing apparatus 1 is a lithography apparatus that performs drawing on a wafer by using charged-particle beams and forms a latent pattern on the wafer by using multiple charged-particle beams emitted from (irradiated by) each of multiple charged-particle optical systems. Here, the charged-particle beams may be electron beams, but are not limited thereto. For example, the charged-particle beams may be ion beams.

The drawing apparatus 1 includes multiple charged-particle optical systems (three charged-particle optical systems that are a first charged-particle optical system 100A, a second charged-particle optical system 100B, and a third charged-particle optical system 100C), a wafer stage 11 (corresponding to each aforementioned holder), and a detection unit 12. The drawing apparatus 1 also includes a blanking controller 13, a processor 14, a deflector controller 15, a position detection processor 16, a stage controller 17, a first memory (storage) 18, a data converter 19, a second memory (storage) 20, and a main controller 21.

The first to third charged-particle optical systems 100A to 100C correspond to one of the three column groups described above, and each emit multiple charged-particle beams. Each of the first to third charged-particle optical systems 100A to 100C also has a function of blanking the multiple charged-particle beams separately and a function of deflecting the multiple charged-particle beams for changing the positions of the multiple charged-particle beams on the wafer.

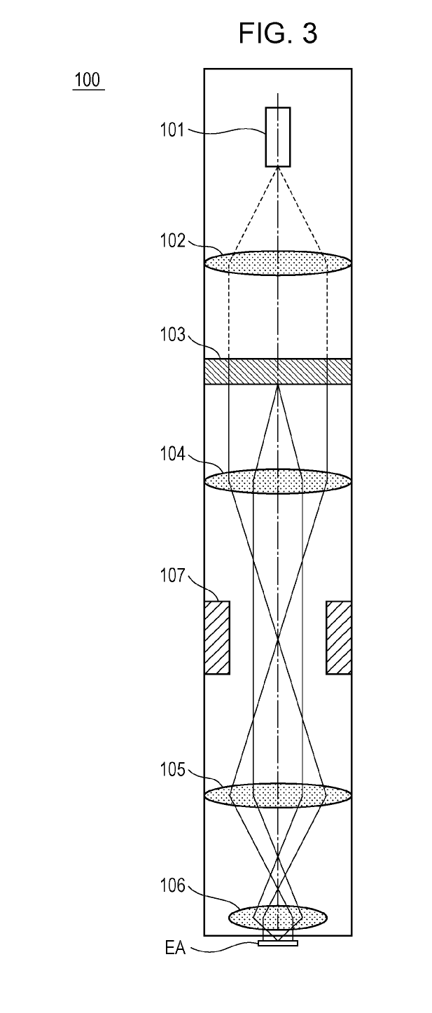

FIG. 3 is a diagram illustrating a configuration example of a charged-particle optical system 100 applicable to each of the first to third charged-particle optical systems 100A to 100C. The charged-particle optical system 100 includes a charged-particle source 101 (electron-beam source), a collimator lens 102, a blanking aperture array 103, an electrostatic lens 104, a magnetic lens 105, an objective lens 106, and a deflector 107.

The charged-particle source 101 is a thermoelectron charge-particle source including an electron emitting material such as LaB₆ or BaO/W (a dispenser cathode). The collimator lens 102 is an electrostatic lens that converges charged-particle beams by using an electric field. The collimator lens 102 causes the charged-particle beams emitted from the charged-particle source 101 to be substantially parallel to each other.

The blanking aperture array 103 is used to divide each of the substantially parallel charged-particle beams emitted from the collimator lens 102 into the multiple charged-particle beams by using two-dimensionally arranged apertures (not illustrated). The blanking aperture array 103 also includes an electrostatic blanking deflector (not illustrated) capable of independently deflecting each of the multiple charged-particle beams and switches between emitting and not emitting each charged-particle beam onto the wafer. Blanking (non-irradiation with) the charged-particle beam may be performed by using not only the configuration as described above including the deflector but also another publicly known configuration.

The electrostatic lens 104 and the magnetic lens 105 collaboratively form an intermediate image to be provided through the respective apertures of the blanking aperture array 103. The objective lens 106 is a magnetic lens and projects the intermediate image on the wafer. The deflector 107 collectively deflects the multiple charged-particle beams from the blanking aperture array 103 to change the positions of the multiple charged-particle beams on the wafer (the position of a drawing region EA).

In FIG. 2, the wafer stage 11 holds a wafer 10 and is movable. The wafer stage 11 includes, for example, an X-Y stage movable in an X-Y plane (horizontal plane) orthogonal to an optical axis of the charged-particle optical system 100, and an electrostatic chuck for holding (attracting) the wafer 10. The wafer stage 11 may also be provided with a detector including apertures which the charged-particle beams enter and detecting the charged-particle beams entering the apertures. The detector may be used to measure characteristics of the charged-particle beams.

The detection unit 12 includes an irradiation system and an image pickup device. The irradiation system emits light having a wavelength that does not cause a resist (photosensitive material) to be photosensitized, the resist being provided for a mark formed on the wafer 10 (such as an alignment mark). The image pickup device picks up an image from regularly reflected light. The detection unit 12 has the multiple detection functions described above, but is not limited thereto, and may be used for acquiring the pieces of information L1, L2, and L3 regarding drawing-target-region coordinates related to the six degrees of freedom and for acquiring the pieces of information E1, E2, and E3 regarding reference-surface (image-surface) coordinates related to the six degrees of freedom. Note that the detection unit 12 is illustrated as a single detection unit having the multiple detection functions in FIG. 2, but is not limited thereto. The detection unit 12 may be provided in such a manner that first, second, and third detection units (detectors) are provided separately or so as to be divided into two.

The first detection unit has a function of detecting the mark on the wafer 10 or the reference mark on the reference member RFM by using radiation beams (such as rays) not causing the resist to be photosensitized. The first detection unit may be used for acquiring information (part of each of the pieces of information L1 to L3) on drawing-target-region coordinates related to the three degrees of freedom (in the X-axis direction, in the Y-axis direction, and around the Z-axis).

The second detection unit has a function of detecting radiation beams (such as electron beams from an electron-optical-system column) for drawing processing, the beams being scattered due to the reference mark on the reference member RFM. The second detection unit may be used for acquiring the pieces of information E1, E2, and E3 regarding reference-surface (image-surface) coordinates related to the six degrees of freedom. The second detection unit may be the detector described above provided on the wafer stage 11 or may include the detector described above.

The third detection unit includes a function of detecting a surface position (position in the Z-axis direction) among measurement positions on the wafer 10 or on the reference member RFM (such as a position near the alignment mark or the reference mark) by using radiation beams (such as rays) not causing the resist to be photosensitized. The third detection unit may be used for acquiring information (the other part of each of the pieces of information L1 to L3) on drawing-target-region coordinates related to the three degrees of freedom (in the Z-axis direction, around the X-axis, and around the Y-axis).

The blanking controller 13 separately controls the blanking aperture arrays 103 of the respective first to third charged-particle optical systems 100A to 100C. The processor 14 includes a buffer memory and a data processing circuit, and generates control data of the first to third charged-particle optical systems 100A to 100C.

The deflector controller 15 separately controls the deflectors 107 of the respective first to third charged-particle optical systems 100A to 100C. The position detection processor 16 generates one of the pieces of the information L1 to L3 and a corresponding one of the pieces of information E1 to E3 described above on the basis of an output (detection result) from the detection unit 12. The stage controller 17 controls positioning of the wafer stage 11 in cooperation with a laser interferometer (corresponding to the aforementioned interferometer) that measures the position of the wafer stage 11.

The first memory 18 stores therein design pattern data for a pattern to be drawn on the wafer 10 (such as design data for a circuit pattern of a semiconductor device). The data converter 19 divides the pattern data stored in the first memory 18 to obtain stripes having a width set in the drawing apparatus 1 and converts the pattern data into intermediate pattern data used for drawing processing. The second memory 20 stores the intermediate pattern data.

The main controller 21 includes a central processing unit (CPU), a memory, and the like, and controls the entire drawing apparatus 1 (components). The main controller 21 transfers the intermediate pattern data to (a buffer memory of) the processor 14 in accordance with a pattern to be drawn on the wafer 10 and comprehensively controls the drawing processing performed by the drawing apparatus 1 by using the foregoing components of the drawing apparatus 1. Note that in the present embodiment, the blanking controller 13, the processor 14, the deflector controller 15, the position detection processor 16, the stage controller 17, the first memory 18, the data converter 19, and the second memory 20 are separately provided, but the configuration related to control of functions of these components is not limited to the configuration described above. For example, a configuration in which the main controller 21 collectively controls the functions may be employed.

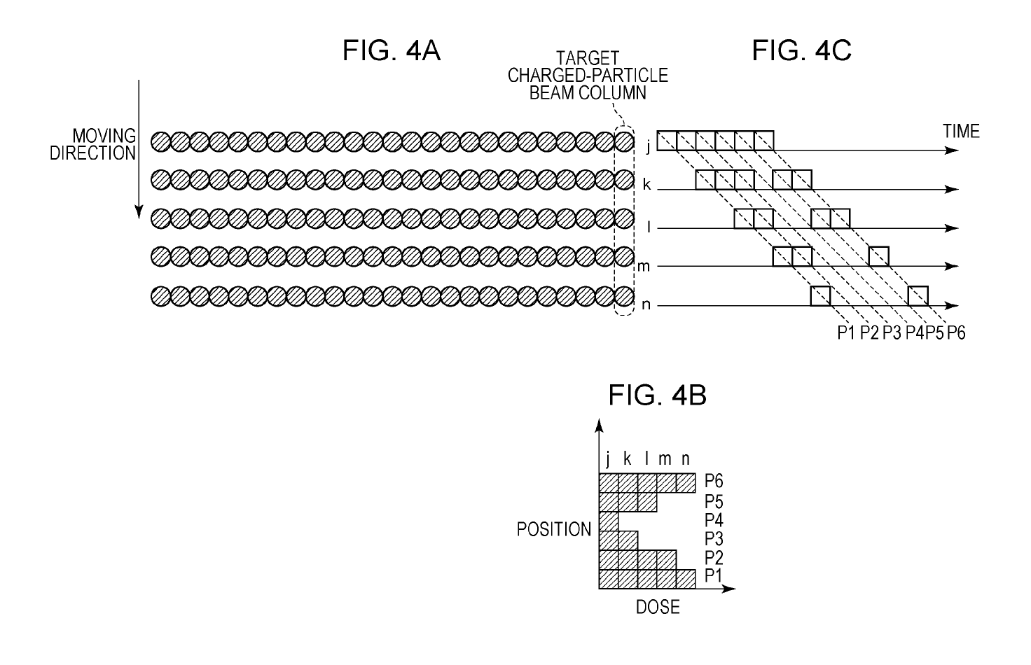

FIGS. 4A, 4B, and 4C are diagrams for explaining the drawing processing performed by the drawing apparatus 1. FIG. 4A is a diagram illustrating an example of arrangement of the multiple charged-particle beams emitted from the charged-particle optical system 100, the arrangement defining the drawing region EA on a wafer. In the present embodiment, the multiple charged-particle beams are arranged in five rows and 20 columns, and a row pitch is two times as large as a column pitch. As described above, the charged-particle optical system 100 emits the multiple charged-particle beams arranged in a first direction (column direction) and in a second direction (row direction) orthogonal to the first direction. The wafer stage 11 moves in a direction from the bottom of the drawing to the top, as illustrated by the arrow in FIG. 4A.

To perform the drawing processing, the main controller 21 controls whether to emit the multiple charged-particle beams arranged in the column direction to the same position (also referred to as a pixel or a grid) on the wafer while continuously moving the wafer stage 11. In other words, the main controller 21 controls the drawing processing to emit the multiple charged-particle beams to a target region on the wafer in a multiplying manner. Here, assume a case where the drawing processing is performed on the wafer by using charged-particle beams in a target column (a charged-particle beam column surrounded by a broken line) among the columns in FIG. 4A to obtain a relationship between positions and doses in FIG. 4B as a relationship between positions P1, P2, P3, P4, P5, and P6 arranged in the column direction on the wafer and doses of the charged-particle beams at the positions P1 to P6. The charged-particle beams are all emitted to the wafer by using the same clock. Rows of the target charged-particle beam column are denoted by j, k, l, m, and n. The wafer stage 11 is continuously moved in the column direction at a velocity of a half of the row pitch per unit clock.

In this case, if turning on/off per unit clock of the charged-particle beams in the rows (j to n) in the target charged-particle beam column (that is, whether to emit the charged-particle beams onto the wafer) is set (controlled) as illustrated in FIG. 4C, the relationship as illustrated in FIG. 4B can be obtained. FIG. 4C schematically illustrates signals of the charged-particle beams in the rows (j to n) emitted at the positions (P1 to P6) on the wafer, the presence and absence of signals being represented by using squares (indicating turning on) and spaces (indicating turning off) that are arranged along broken lines. Note that the wafer stage 11 is moved by a half of the row pitch of the target charged-particle beam column, in a period of two unit clocks. The relationship in FIG. 4B is obtained by adding up, at each position, doses of the charged-particle beams in the rows j, k, l, m, and n, the doses being arranged in such a manner as to be shifted by two unit clocks from each other. Since the tone of the doses is controlled by using the multiplicity of the charged-particle beams arranged in the column direction, the drawing processing is not completed until the positions (P1 to P6) pass under all of the charged-particle beams in the column direction.

### Second Embodiment

A method of manufacturing an article according to an embodiment of the present invention is useful for manufacturing of an article that is, for example, an electronic device such as a semiconductor device, or other element having a fine structure. The method of manufacturing an article may include steps of: forming a pattern (such as a latent pattern) on a wafer by using, for example, the aforementioned lithography apparatus (a drawing apparatus) (a step of drawing on a wafer); and processing (for example, developing the latent pattern) the wafer on which the pattern is formed in the forming step. The method of manufacturing an article may further include other well-known steps (such as oxidation, film forming, deposition, doping, planarization, etching, resist removing, dicing, bonding, and packaging). The method of manufacturing an article according to the present embodiment has an advantage over a conventional method in terms of at least one of the performance, quality, productivity, and production cost of an article.

The embodiments of the present invention have heretofore been described. However, the present invention is not limited to the embodiments, and various modifications may be made without departing from the gist of the invention.

For example, in the description, the drawing apparatus has the long-stroke stage supporting the multiple short-stroke stages (holders) in such a manner that short-stroke stages are movable, the long-stroke stage having a movable range in the X-axis and Y-axis directions larger than the wafer size. However, instead of such a configuration, the drawing apparatus may have multiple long-stroke stages supporting the respective short-stroke stages in such a manner that the short-stroke stages are movable, each of the long-stroke stages having a movable range in the X-axis and Y-axis directions larger than the substrate size. In this case, the long-stroke stages may be moved in synchronization with each other so that each short-stroke stage can be moved in the same manner as in the embodiments described above.

In addition, in a case where each of the multiple optical system groups or the column groups described above includes the multiple optical systems or the columns at respective different positions in the X-axis direction, the long-stroke stage moving in the X-axis direction need not have the movable range in the X-axis direction larger than the wafer size. In the case, the long-stroke stage may have a movable range in the X-axis direction not smaller than a value obtained by dividing the wafer size by the number of optical systems or columns of the optical system group or the column group.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-272044, filed Dec. 27, 2013, which is hereby incorporated by reference herein in its entirety.

What is claimed is:

1. A drawing apparatus comprising:
a plurality of optical systems, each of which irradiates with a beam a substrate, corresponding thereto, having a predetermined size; and
a plurality of holders, each of which is movable and holds the substrate corresponding thereto, wherein
the drawing apparatus is configured to perform drawing on a plurality of the substrate respectively held by the plurality of holders with respective beams respectively by the plurality of optical systems with the plurality of holders being scanned relative to the plurality of optical systems in a scan direction, and
in a direction orthogonal to the scan direction, an interval between two adjacent optical systems of the plurality of optical systems is smaller than a sum of a length of one of the plurality of holders and the size.

2. The apparatus according to claim 1, further comprising a stage configured to support the plurality of holders, and to allow the plurality of holders to be moved independently, and having a movable range not smaller than the size in the scan direction and in the direction orthogonal thereto.

3. The apparatus according to claim 2, wherein
each of the plurality of optical systems includes a deflector for scanning a beam on the substrate corresponding thereto, and
each of the plurality of holders has a movable range relative to the stage larger than a movable range of a beam on a substrate by the deflector in each of the scan direction and the direction orthogonal thereto.

4. The apparatus according to claim 1, further comprising a first detector configured to detect a mark with light, wherein
each of the plurality of holders includes a reference mark to be detected by the first detector.

5. The apparatus according to claim 1, further comprising a second detector configured to detect a mark irradiated by one of the plurality of optical systems with a beam, wherein
each of the plurality of holders includes a reference mark to be detected by the second detector.

6. The apparatus according to claim 2, further comprising a measurement device configured to measure a position of one of the plurality of holders relative to the stage.

7. The apparatus according to claim 3, further comprising a plurality of driving devices configured to respectively move the plurality of holders relative to the stage in each of the scan direction and the direction orthogonal thereto with a resolution smaller than the movable range of the beam.

8. The apparatus according to claim 1, wherein
each of the plurality of holders is movable with respect to at least one of around an axis parallel to the scan direction, around an axis parallel to the direction orthogonal to the scan direction, in a direction along an axis parallel to an optical axis of one of the plurality of optical systems, and around the axis parallel to the optical axis.

9. The apparatus according to claim 1, wherein
each of the plurality of optical systems irradiates the substrate with a plurality of charged-particle beams as the beam.

10. A method of manufacturing an article, the method comprising steps of:
performing drawing on a substrate using a drawing apparatus;
developing the substrate on which the drawing has been performed; and
processing the developed substrate to manufacture the article, wherein
the drawing apparatus includes
a plurality of optical systems, each of which irradiates with a beam a substrate, corresponding thereto, having a predetermined size, and
a plurality of holders, each of which is movable and holds the substrate corresponding thereto,
the drawing apparatus is configured to perform drawing on a plurality of the substrate respectively held by the plurality of holders with respective beams respectively by the plurality of optical systems with the plurality of holders being scanned relative to the plurality of optical systems in a scan direction, and
in a direction orthogonal to the scan direction, an interval between two adjacent optical systems of the plurality of optical systems is smaller than a sum of a length of one of the plurality of holders and the size.

11. A drawing apparatus comprising:
a plurality of optical systems, each of which irradiates with a beam a substrate, corresponding thereto, having a predetermined size; and
a plurality of holders, each of which is movable and holds the substrate corresponding thereto, wherein
the drawing apparatus is configured to perform drawing on a plurality of the substrate respectively held by the plurality of holders with respective beams respectively by the plurality of optical systems with the plurality of holders being scanned relative to the plurality of optical systems in a scan direction, and
the drawing apparatus includes a stage configured to support the plurality of holders, and to allow the plurality of holders to be moved independently, and having a movable range not smaller than the size in the scan direction.

12. The apparatus according to claim 11, wherein
the stage has a movable range, in a direction orthogonal to the scan direction, not smaller than a value obtained by dividing the size by the number of optical systems in the plurality of optical systems.

13. The apparatus according to claim 11, wherein
each of the plurality of optical systems includes a deflector for scanning a beam on the substrate corresponding thereto, and
each of the plurality of holders has a movable range relative to the stage larger than a movable range of a beam on a substrate by the deflector in each of the scan direction and the direction orthogonal thereto.

14. The apparatus according to claim 11, further comprising a first detector configured to detect a mark with light, wherein
each of the plurality of holders includes a reference mark to be detected by the first detector.

15. The apparatus according to claim 11, further comprising a second detector configured to detect a mark irradiated by one of the plurality of optical systems with a beam, wherein
each of the plurality of holders includes a reference mark to be detected by the second detector.

16. The apparatus according to claim 11, further comprising a measurement device configured to measure a position of one of the plurality of holders relative to the stage.

17. The apparatus according to claim 11, further comprising a plurality of driving devices configured to respectively move the plurality of holders relative to the stage in each of the scan direction and the direction orthogonal thereto with a resolution smaller than the movable range of the beam.

18. The apparatus according to claim 11, wherein
each of the plurality of holders is movable with respect to at least one of around an axis parallel to the scan direction, around an axis parallel to the direction orthogonal to the scan direction, in a direction along an axis parallel to an optical axis of one of the plurality of optical systems, and around the axis parallel to the optical axis.

19. The apparatus according to claim 11, wherein
each of the plurality of optical systems irradiates the substrate with a plurality of charged-particle beams as the beam.

20. A method of manufacturing an article, the method comprising steps of:
performing drawing on a substrate using a drawing apparatus;
developing the substrate on which the drawing has been performed; and
processing the developed substrate to manufacture the article, wherein
the drawing apparatus includes
a plurality of optical systems, each of which irradiates with a beam a substrate, corresponding thereto, having a predetermined size, and
a plurality of holders, each of which is movable and holds the substrate corresponding thereto,
the drawing apparatus is configured to perform drawing on a plurality of the substrate respectively held by the plurality of holders with respective beams respectively by the plurality of optical systems with the plurality of holders being scanned relative to the plurality of optical systems in a scan direction, and
the drawing apparatus includes a stage configured to support the plurality of holders, and to allow the plurality of holders to be moved independently, and having a movable range not smaller than the size in the scan direction.
